(19) United States
(12) Patent Application Publication
(10) Pub. No.: US 2008/0230892 A1
(43) Pub. Date: Sep. 25, 2008

(54) Chip package module

(75) Inventors: Chia-Wei CHANG, Hsinchu (TW); Chung-Cheng Lien, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/076,679

(22) Filed: Mar. 21, 2008

(30) Foreign Application Priority Data
Mar. 23, 2007 (TW) 096110108

(51) Int. Cl. H01L 23/49

(52) U.S. Cl. 257/700; 257/E23.024

(57) ABSTRACT

A chip package module is disclosed, which comprises a core plate and two rigid plates individually having a circuit layer. The core plate is sandwiched in between the two rigid plates to form a composite circuit board. Furthermore, the two rigid plates individually have a cavity to expose the surface of the core plate. In addition, the cavities individually have at least one chip disposed therein, and each chip electrically connects to the composite circuit board. The present invention reduces the height of the package module and makes the package module lighter and smaller.

### BACKGROUND OF THE INVENTION

1. Field of the Invention

The present invention relates to a chip package module, more particularly, to a chip package module that exhibits rigidity and flexibility.

2. Description of Related Art

In the development of electronics, the design trend of electronic devices is towards multifunction and high-performance. Thus, high-density integration and miniaturization are necessary for a semiconductor package structure. On the reason aforementioned, the double layer circuit boards are being replaced by the multilayer circuit boards. The area of circuit layout on the circuit board is increased within a restricted space by interlayer connection to meet with the requirement of high-density integration.

In the conventional semiconductor device structure, a semiconductor chip is attached on top of a substrate and then processed in wire bonding. On the other hand, in the advanced semiconductor device structure, a chip is connected to a substrate through bumps by a flip chip package. Therefore high contact pins are provided, but the performance of electronic devices cannot be enhanced and is in fact restricted, owing to the over-long path of circuits and then high impedance for high frequency operation.

As shown in FIG. 1, a conventional semiconductor package module 10 comprises a substrate 11, a first chip 12, and a second chip 13. Herein, one side surface of the substrate 11 has a plurality of solder balls 14 formed thereon to electrically connect to an outer electronic device. The first chip 12 has an active surface and an inactive surface. The inactive surface of the first chip 12 is mounted on the substrate 11 through an epoxy resin 15, and the active surface of the first chip 12 has a plurality of electrode pads 121 thereon. The electrode pads 121 electrically connect to the substrate by metal wires 16. In addition, the second chip 13 is stacked above the first chip 12, and electrically connects to the first chip 12 by a plurality of solder bumps 17. There is a first molding material 18 covering the second chip 13. Furthermore, a second molding material 19 is formed above the surface having the first chip 12 and the second chip 13 to cover the first chip 12.

However, in the aforementioned semiconductor package module, the number of the stacked chips is restricted since the chips are stacked on the substrate. In addition, there are not enough contact pads on the substrate for electrical connecting to additional electronic devices to enhance electrical performance. Furthermore, the semiconductor package module cannot meet with the requirements of high-density integration and miniaturization, owing to the increased height. Thereby, it is an important issue to provide a chip package module that can overcome the difficulties in reducing the height of the package module and enhancing the electrical performance.

### SUMMARY OF THE INVENTION

In order to obviate the aforementioned problems, the present invention provides a chip package module, comprising: a core plate, a first rigid plate, a second rigid plate, a first chip, and a second chip. Herein, the surface of the core plate has a core circuit layer. The first rigid plate is disposed on one side surface of the core plate and has at least one first circuit layer therein to electrically connect to the core circuit layer of the core plate. The surface of the first rigid plate has a plurality of first conductive pads, and the first rigid plate has a first cavity to expose one side surface of the core plate. The second rigid plate is disposed on another surface of the core plate. The second rigid plate has a second circuit layer electrically connecting to the core circuit layer of the core plate and a plurality of second conductive pads thereon. The second rigid plate further has a second cavity corresponding to the first cavity to expose another side surface of the core plate. The second rigid plate, the first rigid plate and the core plate are combined as a composite circuit board. The first chip is embedded and fixed in the first cavity of the first rigid plate and electrically connects to the composite circuit board. In addition, the second chip is embedded and fixed in the second cavity of the second rigid plate and electrically connects to the composite circuit board.

In the chip package module of the present invention, the materials of the first and second conductive pads are independently selected from the group consisting of Cu, Ag, Au, Ni/Au, Ni/Pd/Au and the combination thereof. Preferably, the materials of the first and second conductive pads are Cu.

The chip package module of the present invention further comprises a molding material to encapsulate the first and second chips. Preferably, the material of the molding material is selected from the group consisting of an epoxy resin and a siloxane resin.

The aforementioned first chip can electrically connect to the first conductive pads of the first rigid plate of the composite circuit board by bonding wires, and is fixed on the surface of the core plate exposed by the first cavity through an adhesive material. As aforementioned, the second chip can electrically connect to the second conductive pads of the second rigid plate of the composite circuit board by bonding wires, and is fixed on the surface of the core board exposed by the second cavity through an adhesive material. Herein, the material of the adhesive material can be selected from the group consisting of a resin and a film tape.

In the aforementioned chip package module of the present invention, the surface of the core plate exposed by the first cavity or that exposed by the second cavity can have a plurality of third conductive pads formed thereon. The material of the aforementioned third conductive pads can be selected from the group consisting of Cu, Ag, Au, Ni/Au, Ni/Pd/Au and the combination thereof. Preferably, the material of the third conductive pads is Cu.

In the chip package module of the present invention, the first chip embedded and fixed in the first cavity or the second chip embedded and fixed in the second cavity can electrically connect to the aforementioned third conductive pads by solder bumps.

In the chip package module of the present invention, the first cavity of the first rigid plate can further have a third chip disposed therein. The third chip electrically connects to the first conductive pads of the first rigid plate of the composite circuit board by bonding wires and is attached to the first chip by a connection layer. The first chip electrically connects to the third conductive pads of the core plate of the composite circuit board by solder bumps. As aforementioned, the second cavity of the second rigid plate also can further have a third chip disposed therein. The third chip electrically connects to the second conductive pads of the second rigid plate of the composite circuit board by bonding wires and is attached to the second chip by a connection layer. The second chip electrically connects to the third conductive pads of the core plate of the composite circuit board by solder bumps. Herein, the material of the aforementioned connection layer can be selected from the group consisting of a resin and a film tape.

In the chip package module of the present invention, the composite circuit board can electrically connect to an outer electronic device by the first conductive pads of the first rigid plate or the second conductive pads of the second rigid plate. Herein, the outer electronic device electrically connecting to the first conductive pads can be a circuit board, and the outer electronic device electrically connecting to the second conductive pads can be selected from the group consisting of a flip-chip package, a ball grid array package, and a chip package module.

Accordingly, the present invention can overcome the difficulties in reducing the height of the package module and enhancing the electrical performance.

Other objects, advantages, and novel features of the invention will become more apparent from the following detailed description when taken in conjunction with the accompanying drawings.

### BRIEF DESCRIPTION OF THE DRAWINGS

FIG. 1 is a cross-section view of a conventional semiconductor package module;

FIG. 2 is a cross-section view of a chip package module of a preferred embodiment;

FIGS. 3 to 7 are a cross-section views of chip package modules of other preferred embodiments; and

FIG. 8 is a cross-section view of a chip package module connecting to outer electronic devices of another preferred embodiment.

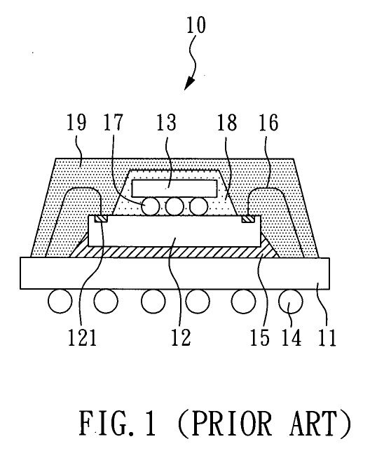

### DETAILED DESCRIPTION OF THE PREFERRED EMBODIMENT

### Embodiment 1

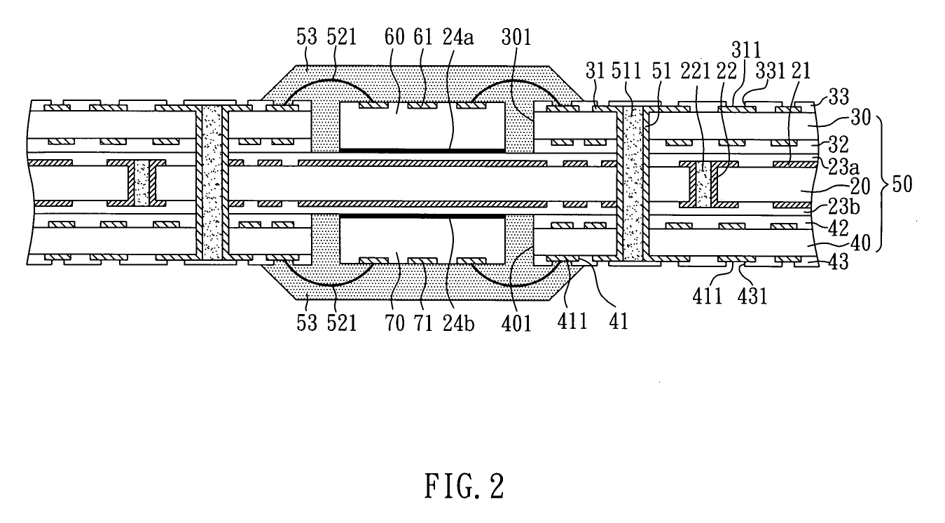

With reference to FIG. 2, there is shown a cross-section view of a chip package module in the present embodiment. In the present embodiment, a core plate 20 is provided, and the core plate 20 is a flexible circuit board that exhibits suitable mechanical strength and thereby can carry the chips in the following process. There are a core circuit layer 21 formed on the two side surfaces of the core plate 20 and plated through holes 22 formed in the core plate 20 by machine-drilling and then electroplating. The plated through holes 22 have an insulating material 221 therein. The plated through holes 22 in the core plate 20 can electrically connect the core circuit layer 21 on the two side surfaces of the core plate 20. In addition, the two side surfaces of the core plate 20 are laminated with a cover layer 23a, 23b to protect the core plate 20. Herein, the material of the cover layer 23a, 23b is a photosensitive dielectric material. The material of the core circuit layer 21 can be selected from the group consisting of Cu, Ag, Au, Ni/Au, Ni/Pd/Au and the combination thereof. In the present invention, the material of the core circuit layer 21 is Cu.

Then, a first rigid plate 30 having a first cavity 301 and a second rigid plate 40 having a second cavity 401 are provided. In the present embodiment, the first and second rigid plates are rigid circuit boards. Herein, a first cavity 301 can be formed in the first rigid plate 30 by mill cutting first, and then the first rigid plate 30 is disposed on one side surface of the core plate 20. The first rigid plate 30 has a first circuit layer 31 therein, and the first circuit layer 31 of the first rigid plate 30 can be double-layered or multi-layered. In addition, a second cavity 401 can be formed in the second rigid plate 40 by mill cutting first, and then the second rigid plate 40 is disposed on another side surface of the core plate 20. The second rigid plate 40 has a second circuit layer 41 therein, and the second circuit layer 41 of the second rigid plate 40 can be double-layered or multi-layered. Herein, the materials of the first and second circuit layers can be independently selected from the group consisting of Cu, Ag, Au, Ni/Au, Ni/Pd/Au and the combination thereof. In the present embodiment, the materials of the first and second circuit layers are Cu.

The aforementioned first rigid plate 30 is laminated on one surface of the core plate 20 by an adhesive layer 32. The material of the adhesive layer 32 is prepreg. Similarly, the second rigid plate 40 is also laminated on another surface of the core plate 20 by an adhesive layer 42. The material of the adhesive layer 42 also can be prepreg. The second cavity 401 corresponds to the first cavity 301. Accordingly, the first rigid plate 30 and the second rigid plate 40 are laminated on the surfaces of the core plate 20. Subsequently, through holes 40 extending through the first rigid plate 30, the core plate 20, and the second rigid plate 40 are formed by machine-drilling, and then plated through holes 51 are formed by electroplating. The plated through holes 51 have an insulating material 511 therein. The plated through holes 51 can electrically connect the core circuit layer 21 of the core plate 20 with the first circuit layer 31 of the first rigid plate 30 and the second circuit layer 41 of the second rigid plate 40. Hereafter, a patterned solder mask 33 can be formed on the outer surface of the first rigid plate 30, and openings 331 can be formed to expose the part surface of the first circuit layer 31 so as to form first conductive pads 311. A patterned solder mask 43 also can be formed on the outer surface of the second rigid plate 40, and openings 431 can be formed to expose the part surface of the second circuit layer 41 so as to form second conductive pads 411. Accordingly, a composite circuit board 50 is accomplished.

Subsequently, a first chip 60 is embedded and fixed in the first cavity 301 of the first rigid plate 30 of the composite circuit board 50. The first chip 60 has an active surface and an inactive surface. The inactive surface of the first chip 60 is fixed on the surface of the cover layer 23a of the core plate 20 by an adhesive material 24a, and the active surface of the first chip 60 has a plurality of electrode pads 61 disposed thereon. Herein, the material of the adhesive material 24a can be selected from the group consisting of a resin and a film tape. In the present embodiment, the material of the adhesive material 24a is a resin. In addition, a second chip 70 is embedded and fixed in the second cavity 401 of the second rigid plate 40. Similarly, the second chip 70 also has an active surface and an inactive surface. The active surface of the second chip 70 has a plurality of electrode pads 71 disposed thereon, and the inactive surface of the second chip 70 is fixed on the surface of the other cover layer 23b of the core plate 20 by an adhesive material 24b. The material of the adhesive material 24b used to fix the second chip 70 can be the same as the material of the adhesive material 24a used to fix the first chip 60.

Then, the electrode pads 61 on the active surface of the first chip 60 in the composite circuit board 50 can electrically connect to the first conductive pads 311 of the first rigid plate 30 in the composite circuit board 50 by bonding wires 521. The bonding wires 521 can be gold wires. In the present embodiment, the bonding wires 521 are gold wires. Similarly, the electrode pads 71 on the active surface of the second chip 70 in the composite circuit board 50 also electrically connect to the second conductive pads 411 of the second rigid plate 40 in the composite circuit board 50 by bonding wires 521. Finally, the chip package module is accomplished.

In addition, a molding material 53 can be formed above the surface having the first chip 60 to encapsulate the first chip 60 and the bonding wires 521 so as to protect the first chip 60. Herein, the material of the molding material 53 can be selected from the group consisting of an epoxy resin and a siloxane resin. In the present embodiment, the material of the molding material 53 is an epoxy resin. The molding material 53 also can be formed above the surface having the second chip 70 to encapsulate the second chip 70 and the bonding wires 521 so as to protect the second chip 70.

Accordingly, the chip package module of the present invention comprises: a core plate 20, a first rigid plate 30, a second rigid plate 40, a first chip 60, and a second chip 70. Herein, the surface of the core plate 20 has a core circuit layer 21. The first rigid plate 30 is disposed on one side surface of the core plate 20 and has at least one first circuit layer 31 therein to electrically connect the core circuit layer 21 of the core plate 20. The surface of the first rigid plate 30 has a plurality of first conductive pads 311, and the first rigid plate 30 has a first cavity 301 to expose one side surface of the core plate 20. The second rigid plate 40 is disposed on another surface of the core plate 20. The second rigid plate 40 has a second circuit layer 41 electrically connecting to the core circuit layer 21 of the core plate 20 and a plurality of second conductive pads 41 thereon. The second rigid plate 40 further has a second cavity 401 corresponding to the first cavity 301 to expose another side surface of the core plate 20. The second rigid plate 40, the first rigid plate 30 and the core plate 20 are combined as a composite circuit board 50. The first chip 60 is embedded and fixed in the first cavity 301 of the first rigid plate 30 and electrically connects to the composite circuit board 50. In addition, the second chip 70 is embedded and fixed in the second cavity 401 of the second rigid plate 40 and electrically connects to the composite circuit board 50.

### Embodiment 2

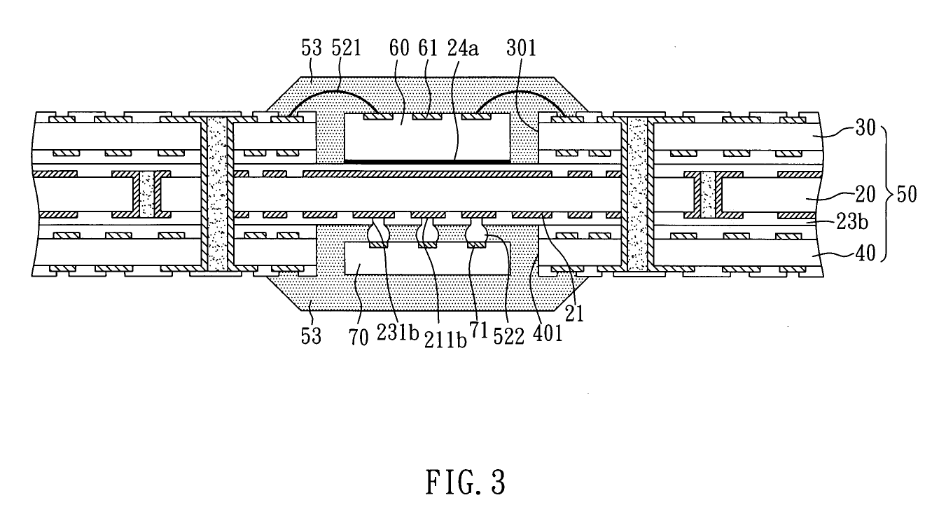

With reference to FIG. 3, there is shown a cross-section view of a chip package module in the present embodiment. The present embodiment is the same as Embodiment 1 (as shown in FIG. 2), except that the cover layer 23b disposed on the surface having the second chip 70 placed there above has a plurality of openings 231b to expose the surface of the core circuit layer 20 for third conductive pads 211b. The third conductive pads 211b formed on the core plate 20 in the composite circuit board 50 can electrically connect to the electrode pads 71 on the active surface of the second chip 70 by solder bumps.

### Embodiment 3

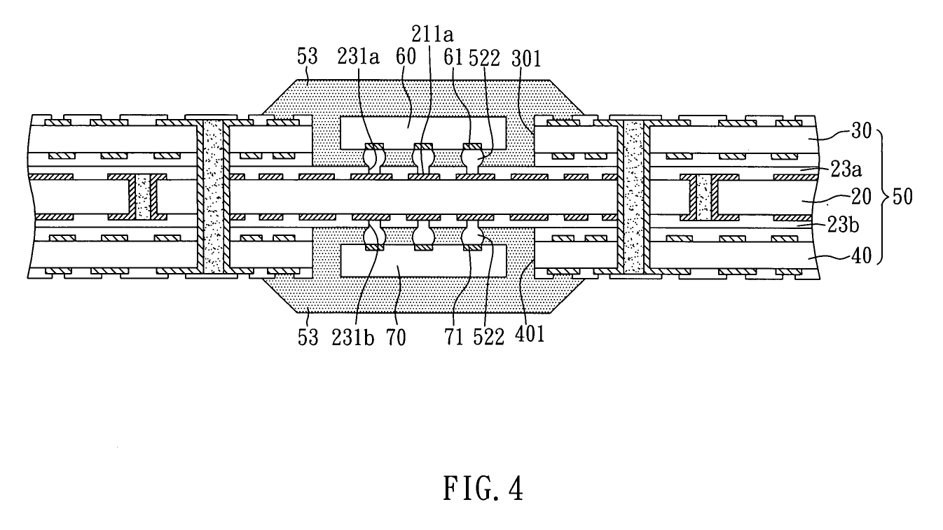

With reference to FIG. 4, there is shown a cross-section view of a chip package module in the present embodiment. The present embodiment is the same as Embodiment 2 (as shown in FIG. 3), except that the cover layer 23a disposed on the surface having the first chip 60 placed there above has a plurality of openings 231a to expose the surface of the core circuit layer 20 for third conductive pads 211a. The third conductive pads 211a formed on the core plate 20 in the composite circuit board 50 can electrically connect to the electrode pads 61 on the active surface of the first chip 60 by solder bumps.

### Embodiment 4

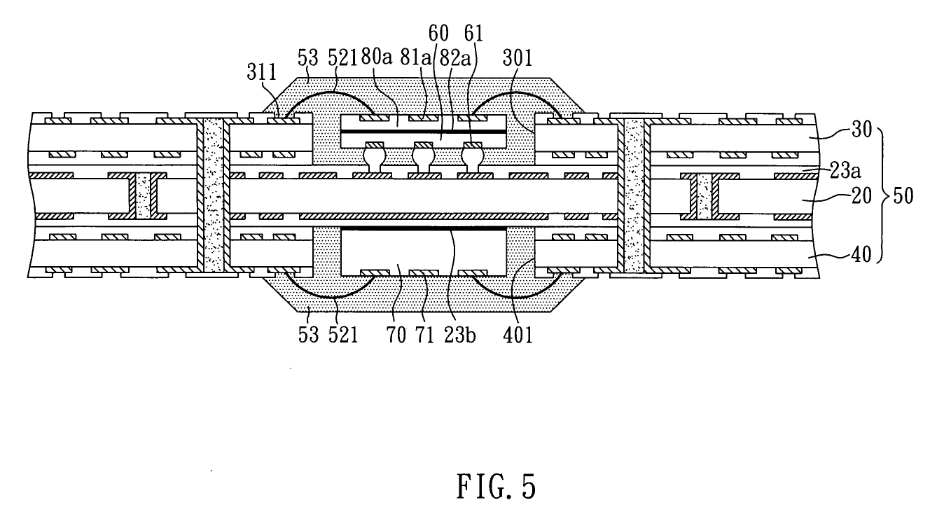

With reference to FIG. 5, there is shown a cross-section view of a chip package module in the present embodiment. The configuration of the second chip 70 disposed in the composite circuit board 50 is the same as that in Embodiment 1 (as shown in FIG. 2) and the configuration of the first chip 60 disposed in the composite circuit board 50 is the same as that in Embodiment 3, except that the inactive surface of the first chip 60 has a third chip 80a disposed thereon. Similarly, the third chip 80a has an active surface and an inactive surface, and the inactive surface of the third chip 80a is attached to the first chip 60 by a connection layer 82a. Herein, the material of the connection layer 82a is selected from the group consisting of a resin and a film tape. In the present embodiment, the material of the connection layer 82a is a resin. In addition, the electrode pads 81a on the active surface of the third chip 80a in the present embodiment electrically connect to the first conductive pads 311 of the first rigid plate 30 in the composite circuit board 50 by bonding wires 521.

### Embodiment 5

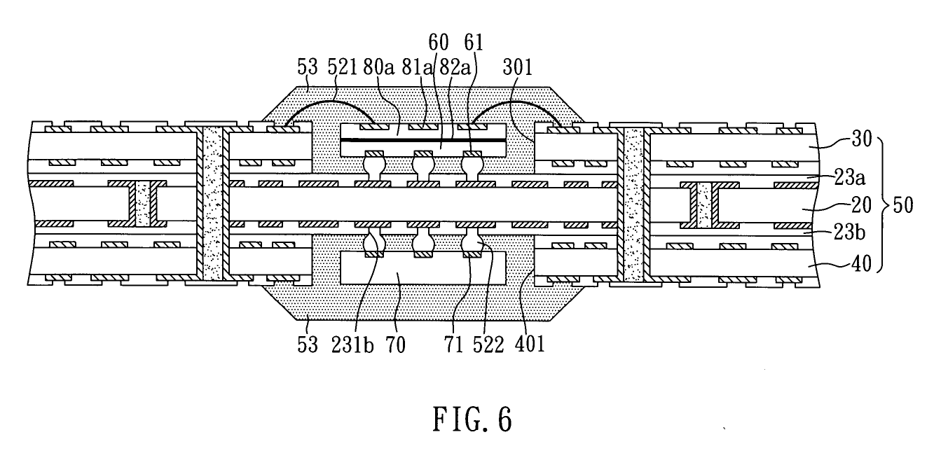

With reference to FIG. 6, there is shown a cross-section view of a chip package module in the present embodiment. The present embodiment is the same as Embodiment 4 (as shown in FIG. 5), except that the configuration of the second chip 70 disposed in the composite circuit board 50 is the same as that in Embodiment 2.

### Embodiment 6

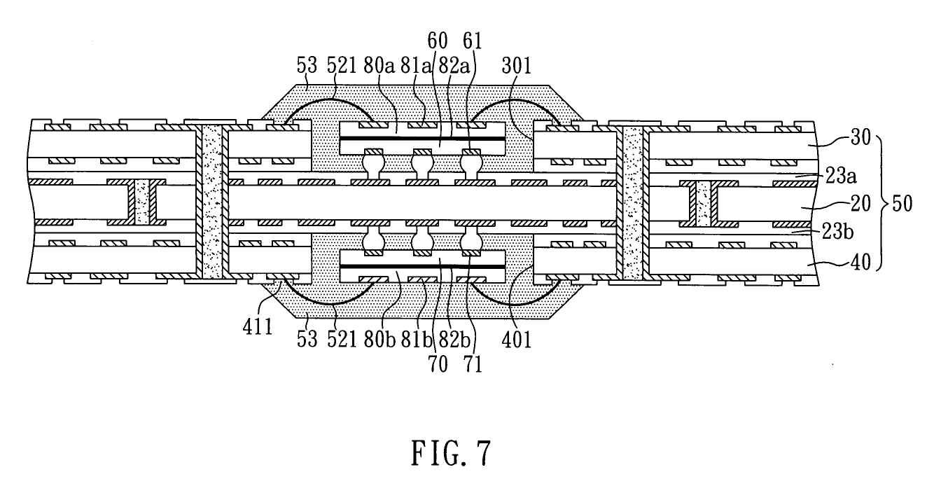

With reference to FIG. 7, there is shown a cross-section view of a chip package module in the present embodiment. The present embodiment is the same as Embodiment 5 (as shown in FIG. 6), except that the second cavity 401 of the second rigid plate 40 also has a third chip 80b disposed therein, the active surface of the third chip 80b has a plurality of electrode pads 81b, and the inactive surface of the third chip 80b is attached to the second chip 70 by a connection layer 82b. In addition, the electrode pads 81b on the active surface of the third chip 80b of the present embodiment electrically connect to the second conductive pads 411 of the second rigid plate 30 in the composite circuit board 50 by bonding wires.

### Embodiments 7˜12

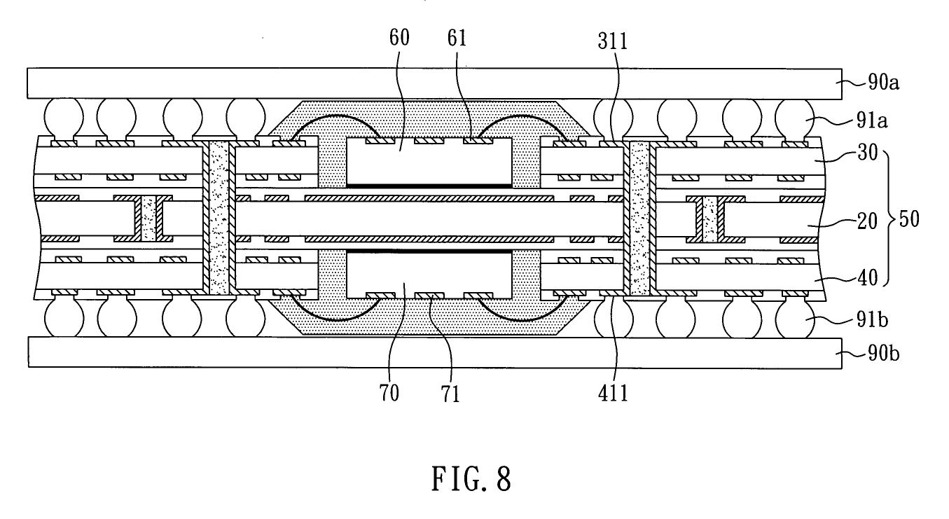

With reference to FIG. 8, there is shown a cross-section view of a chip package module connecting to outer electronic devices 90a and 90b. As shown in FIG. 8, the chip package module (as shown in FIG. 2) of Embodiment 1 is provided. In Embodiment 7, the first conductive pads 311 on the surface of the first rigid plate 30 in the composite circuit board 50 having the first chip 60 and the second chip 70 electrically connect to the outer electronic device 90a by solder balls 91a. The outer electronic device 90a is a circuit board. Similarly, the second conductive pads 411 on the surface of the second rigid plate 40 also electrically connect to the other outer electronic device 90b by solder balls 91b. The outer electronic device 90b is selected from the group consisting of a flip-chip package, a ball grid array package, and the chip package modules provided by Embodiments 1˜6. For example, in the present embodiment, the outer electronic device 90b is a flip-chip package. Herein, the first rigid plate 30 also can electrically connect to the outer electronic device 90b (in the present embodiment, the outer electronic device 90b is a flip-chip package) while the second rigid plate 40 can electrically connect to the outer electronic device 90a (in the present embodiment, the outer electronic device 90a is a circuit board).

Similarly, in Embodiments 8˜12, the chip package modules provided by Embodiments 2˜6 electrically connect to outer electronic devices, respectively. The configurations of the chip package modules attached to outer electronic devices in Embodiments 8˜12 are the same as that in Embodiment 7 so as to provide the chip package modules connecting to outer electronic devices.

Accordingly, the present invention can reduce the height of the package module and enhance the electrical performance by the electrical connection to outer electronic devices so as to overcome the difficulties in reducing the height of the package module and enhancing the electrical performance.

What is claimed is:

1. A chip package module, comprising:
a core plate having a core circuit layer on the surface thereof;
a first rigid plate disposed on one side surface of the core plate, wherein the first rigid plate has at least one first circuit layer therein to electrically connect to the core circuit layer of the core plate, the surface of the first rigid plate has a plurality of first conductive pads, and the first rigid plate has a first cavity to expose one side surface of the core plate;
a second rigid plate disposed on another side surface of the core plate, wherein the second rigid plate has at least one second circuit layer electrically connecting to the core circuit layer of the core plate, a plurality of second conductive pads on the surface thereof, and a second cavity corresponding to the first cavity to expose another side surface of the core plate, and the second rigid plate, the first rigid plate and the core plate are combined as a composite circuit board;
a first chip embedded and fixed in the first cavity of the first rigid plate and electrically connecting to the composite circuit board; and
a second chip embedded and fixed in the second cavity of the second rigid plate and electrically connecting to the composite circuit board.

2. The chip package module as claimed in claim 1, wherein the materials of the first and second conductive pads are independently selected from the group consisting of Cu, Ag, Au, Ni/Au, Ni/Pd/Au and the combination thereof.

3. The chip package module as claimed in claim 1, further comprising a molding material to encapsulate the first chip.

4. The chip package module as claimed in claim 1, wherein the first chip electrically connects to the first conductive pads of the first rigid plate of the composite circuit board by bonding wires, and is fixed on the surface of the core plate exposed by the first cavity through an adhesive material.

5. The chip package module as claimed in claim 1, wherein the surface of the core plate exposed by the first cavity has a plurality of third conductive pads formed thereon.

6. The chip package module as claimed in claim 5, wherein the material of the third conductive pads is selected from the group consisting of Cu, Ag, Au, Ni/Au, Ni/Pd/Au and the combination thereof.

7. The chip package module as claimed in claim 5, wherein the first chip electrically connects to the third conductive pads by solder bumps.

8. The chip package module as claimed in claim 5, wherein the first cavity of the first rigid plate further has a third chip disposed therein, the third chip electrically connects to the first conductive pads of the first rigid plate in the composite circuit board by bonding wires, the third chip is attached to the first chip by a connection layer, and the first chip electrically connects to the third conductive pads of the core plate in the composite circuit board by solder bumps.

9. The chip package module as claimed in claim 1, further comprising a molding material to encapsulate the second chip.

10. The chip package module as claimed in claim 1, wherein the second chip electrically connects to the second conductive pads of the second rigid plate in the composite circuit board by bonding wires, and is fixed on the surfaces of the core plate exposed by the second cavity by an adhesive material.

11. The chip package module as claimed in claim 1, wherein the surface of the core plate exposed by the second cavity has a plurality of third conductive pads formed thereon.

12. The chip package module as claimed in claim 11, wherein the material of the third conductive pads is selected from the group consisting of Cu, Ag, Au, Ni/Au, Ni/Pd/Au and the combination thereof.

13. The chip package module as claimed in claim 11, wherein the second chip electrically connects to the third conductive pads by solder bumps.

14. The chip package module as claimed in claim 11, wherein the second cavity of the second rigid plate further has a third chip disposed therein, the third chip electrically connects to the second conductive pads of the second rigid plate in the composite circuit board by bonding wires, the third chip is attached to the second chip by a connection layer, and the second chip electrically connects to the third conductive pads of the core plate in the composite circuit board by solder bumps.

15. The chip package module as claimed in claim 1, wherein the composite circuit board electrically connects to an outer electronic device by the first conductive pads of the first rigid plate.

16. The chip package module as claimed in claim 11, wherein the outer electronic device is a circuit board.

17. The chip package module as claimed in claim 1, wherein the composite circuit board can electrically connect to an outer electronic device by the second conductive pads of the second rigid plate.

18. The chip package module as claimed in claim 17, wherein the outer electronic device is selected from the group consisting of a flip-chip package, a ball grid array package, and a chip package module.
